(19) United States
(12) Patent Application Publication
(10) Pub. No.: US 2026/0150251 A1
(43) Pub. Date: May 28, 2026

(54) Cabinet Heat Dissipation System And Control Method And Device Thereof

(71) Applicant: Vertiv Tech Co., Ltd., Shenzhen (CN)

(72) Inventors: Shuai WANG, Xi'an (CN); Junchao WANG, Xi'an (CN); Shiying XIAO, Xi'an (CN); Xueji ZHOU, Xi'an (CN); Xing LI, Xi'an (CN)

(73) Assignee: Vertiv Tech Co., Ltd., Shenzhen (CN)

(21) Appl. No.: 19/184,241

(22) Filed: Apr. 21, 2025

(30) Foreign Application Priority Data
Nov. 26, 2024 (CN) 2024117160374

(51) Int. Cl. H05K 7/20

(52) U.S. Cl. CPC H05K 7/20836; H05K 7/20254; H05K 7/20263; H05K 7/20272; H05K 7/20736; H05K 7/20781

(57) ABSTRACT

Provided in the present disclosure are a cabinet heat dissipation system and a control method and device thereof, for achieving a one-stop management of heat dissipation of a cabinet and improving an intelligence degree of heat dissipation control of the cabinet. The cabinet heat dissipation system includes: a controller, a cooling distribution unit CDU, and a liquid dispensing unit and an air-liquid heat exchanger for heat dissipation of the cabinet, wherein a primary side of the CDU is connected to a cold source, and a liquid outlet at a secondary side of the CDU is connected to an inlet of the liquid dispensing unit and an inlet of the air-liquid heat exchanger, respectively, through a first control valve; an outlet of the air-liquid heat exchanger is connected to the inlet of the liquid dispensing unit and a liquid return port at a secondary side of the CDU, respectively, through a second control valve; an outlet of the liquid dispensing unit is connected to the liquid return port at the secondary side of the CDU; and the controller is configured to adjust a heat dissipation capacity of the cabinet heat dissipation system according to a preset control strategy.

### CROSS-REFERENCE TO RELATED APPLICATION

This application claims priority to Chinese Patent Application No. 202411716037.4, titled “CABINET HEAT DISSIPATION SYSTEM AND CONTROL METHOD AND DEVICE THEREOF”, filed on Nov. 26, 2024, with the China National Intellectual Property Administration, the entire disclosure of which is incorporated herein by reference.

### FIELD

The present disclosure relates to the technical field of cabinets, and in particular to a cabinet heat dissipation system, a control method and device thereof.

### BACKGROUND

With the development of data centers, the density of single cabinets is increased continuously. The traditional air-cooling mode can no longer meet the demands for heat dissipation, and the energy efficiency thereof cannot meet relevant requirements. In the future, data centers face various challenges in energy consumption and heat dissipation. A liquid cooling solution has become a development trend of future data centers. Cold plate liquid cooling is widely used as a relatively mature method for liquid cooling.

In practice, liquid cooling and air cooling are often used in combination with each other. When they are used together, the air-liquid system and the liquid cooling system are separated from each other, each requiring an independent liquid cooling system, which is difficult to manage in one stop, and the intelligence degree of control is low.

### SUMMARY

The present disclosure provides a cabinet heat dissipation system, and a control method and device thereof, with which one-stop management of heat dissipation of a cabinet is achieved, and an intelligence degree of heat dissipation control of the cabinet is improved.

In a first aspect, a cabinet heat dissipation system is provided in an embodiment of the present disclosure. The system includes: a controller, a cooling distribution unit (CDU), and a liquid dispensing unit and an air-liquid heat exchanger for heat dissipation of the cabinet, where a primary side of the CDU is connected to a cold source, and a liquid outlet at a secondary side of the CDU is connected to an inlet of the liquid dispensing unit and an inlet of the air-liquid heat exchanger, respectively, through a first control valve; an outlet of the air-liquid heat exchanger is connected to the inlet of the liquid dispensing unit and a liquid return port at a secondary side of the CDU, respectively, through a second control valve; an outlet of the liquid dispensing unit is connected to the liquid return port at the secondary side of the CDU; and the controller is configured to adjust a heat dissipation capacity of the cabinet heat dissipation system according to a preset control strategy.

In the system, the cabinet heat dissipation system includes the CDU, the air-liquid heat exchanger and the liquid dispensing unit. The primary side of the CDU is connected to the cold source, and the secondary side of the CDU is connected to the air-liquid heat exchanger and the liquid dispensing unit to provide a cooling medium for the air-liquid heat exchanger and the liquid dispensing unit. In other words, the cooling medium for the air-liquid heat exchanger and the liquid dispensing unit is provided by the CDU. By adjusting a temperature and/or flow rate of the cooling medium provided by the CDU, the heat dissipation capacity of the heat dissipation system can be adjusted, which contributes to one-stop management.

In the embodiment of the present disclosure, the first control valve is disposed in a pipeline of the liquid outlet at the secondary side of the CDU, and the second control valve is disposed on an outlet side of the air-liquid heat exchanger. By adjusting a flow direction of the cooling medium of the first control valve and the second control valve, a connection relationship between the liquid dispensing unit and the air-liquid heat exchanger can be changed, and thereby a heat dissipation mode of the cabinet heat dissipation system can be adjusted. By adjusting an opening degree of the first control valve and the second control valve, an air-to-liquid ratio can be adjusted. Thereby, intelligent control of the cabinet heat dissipation system can be realized, and energy consumption saving can be maximized.

In a possible implementation, the controller is configured to adjust a heat dissipation capacity of the cabinet heat dissipation system in one or more of: adjusting a temperature and/or flow rate of a cooling medium at the liquid outlet at the secondary side of the CDU; adjusting an opening degree of the first control valve and/or the second control valve; and switching a heat dissipation mode of the cabinet heat dissipation system.

In the system, the heat dissipation capacity of the heat dissipation system may be adjusted flexibly through a combination of various manners, when adjusting the heat dissipation capacity of the heat dissipation system.

In a possible implementation, heat dissipation modes of the cabinet heat dissipation system at least include a first heat dissipation mode, a second heat dissipation mode and a third heat dissipation mode; in the first heat dissipation mode, the liquid outlet at the secondary side of the CDU is connected to the inlet of the air-liquid heat exchanger, the outlet of the air-liquid heat exchanger is connected to the inlet of the liquid dispensing unit, and the outlet of the liquid dispensing unit is connected to the liquid return port at the secondary side of the CDU; in the second heat dissipation mode, the liquid outlet at the secondary side of the CDU is connected to the inlet of the air-liquid heat exchanger and the inlet of the liquid dispensing unit, the outlet of the air-liquid heat exchanger is connected to the inlet of the liquid dispensing unit, and the outlet of the liquid dispensing unit is connected to the liquid return port at the secondary side of the CDU; and in the third heat dissipation mode, the liquid outlet at the secondary side of the CDU is connected to the inlet of the air-liquid heat exchanger and the inlet of the liquid dispensing unit, and the outlet of the air-liquid heat exchanger and the outlet of the liquid dispensing unit are both connected to the liquid return port at the secondary side of the CDU.

In the system, in the first heat dissipation mode, the air-liquid heat exchanger and the liquid dispensing unit are connected in series, and the cooling medium passes through the air-liquid heat exchanger first and then through the liquid dispensing unit. In the second heat dissipation mode, the air-liquid heat exchanger and the liquid dispensing unit are connected in series, and the CDU provides the cooling medium for the liquid dispensing unit. In the third heat dissipation mode, the air-liquid heat exchanger and the liquid dispensing unit are connected in parallel, and the cooling medium passes through the air-liquid heat exchanger and the liquid dispensing unit separately. The cooling capacity provided is different depending on the three heat dissipation modes, and can be flexibly switched according to a power consumption requirement of the cabinet, so as to reduce energy consumption.

In a possible implementation, the air-liquid heat exchanger includes a coiled radiator.

In the system, the air-liquid heat exchanger includes merely a coiled radiator, which dissipates heat from the cabinet by using a fan of a device (such as a cold plate liquid-cooled server) in the cabinet. Such configuration has no fan and is applicable for a scenario in which the power density is low, thereby reducing energy consumption.

In a possible implementation, the air-liquid heat exchanger further includes at least one fan.

In the system, the air-liquid heat exchanger includes a coiled radiator and at least one fan, and assists and accelerates the heat dissipation from the cabinet by the fan, while dissipating heat from the cabinet by using a fan of a cold plate liquid-cooled server, which is applicable for a scenario in which the power density is medium or large.

In the second aspect, a control method of a cabinet heat dissipation system is provided in an embodiment of the present disclosure. The method is applied to the cabinet heat dissipation system provided in the first aspect of the embodiment of the present disclosure. The method includes: obtaining an operating parameter of the cabinet heat dissipation system; adjusting a heat dissipation capacity of the cabinet heat dissipation system using a first adjustment manner, in case of determining, based on the operating parameter, that the cabinet heat dissipation system meets a first exception condition.

In the method, in a case where it is determined that the cabinet heat dissipation system has abnormal heat dissipation based on the operating parameter of the cabinet heat dissipation system, the heat dissipation capacity of the cabinet heat dissipation system is adjusted using the first adjustment manner. For example, in case that the heat dissipation mode remains unchanged, the heat dissipation capacity of the heat dissipation system is adjusted by adjusting a temperature and/or flow rate of the cooling medium at the liquid outlet at the secondary side of the CDU, and/or by adjusting the opening degree of the control valve, so as to ensure a normal operation of the cabinet.

In a possible implementation, the first adjustment manner includes one or more of: adjusting a temperature and/or flow rate of a cooling medium at the liquid outlet at the secondary side of the CDU; and adjusting an opening degree of the first control valve.

In a possible implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In a possible implementation, the adjusting a heat dissipation capacity of the cabinet heat dissipation system using a first adjustment manner, in case of determining, based on the operating parameter, that the cabinet heat dissipation system meets a first exception condition, includes one or more of: determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval; determining that the cabinet heat dissipation system meets the first exception condition and decreasing a cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, where the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1; determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval; determining that the cabinet heat dissipation system meets the first exception condition and adjusting an opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval; determining that the cabinet heat dissipation system meets the first exception condition and adjusting an opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval; determining that the cabinet heat dissipation system meets the first exception condition and increasing a cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate; determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and determining that the cabinet heat dissipation system meets the first exception condition and adjusting an opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

In a possible implementation, the method further includes: re-obtaining the operating parameter of the cabinet heat dissipation system, after adjusting the heat dissipation capacity of the cabinet heat dissipation system at least once using the first adjustment manner; and adjusting the heat dissipation capacity of the cabinet heat dissipation system using a second adjustment manner, in case of determining, based on the re-obtained operating parameter, that the cabinet heat dissipation system meets a second exception condition.

In the method, in a case where heat dissipation of the cabinet heat dissipation system is still abnormal after at least one adjustment using the first adjustment manner, the heat dissipation capacity of the cabinet heat dissipation system is then adjusted using the second manner, such as switching the heat dissipation mode, thereby the normal operation of the cabinet being ensured.

In the embodiment of the present disclosure, the heat dissipation capacity of the cabinet heat dissipation system is adjustment through a combination of the first adjustment manner and the second adjustment manner. In this way, the heat dissipation capacity of the cabinet heat dissipation system can be adjusted more accurately, so that the cabinet heat dissipation system can be adapted to more application scenarios and energy consumption can be reduced.

In a possible implementation, the second adjustment manner includes: switching a heat dissipation mode of the cabinet heat dissipation system.

In a possible implementation, the adjusting of the heat dissipation capacity of the cabinet heat dissipation system using a second adjustment manner, in case of determining, based on the re-obtained operating parameter, that the cabinet heat dissipation system meets a second exception condition, includes one or more of: determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

In a possible implementation, an operating time interval of each heat dissipation mode of the cabinet heat dissipation system is longer than a preset time interval.

In the method, the operation time interval of each heat dissipation mode is set to be longer than the preset time interval. In this way, influence on the operation of the heat dissipation system due to frequent switching of the heat dissipation mode can be avoided.

In a third aspect, a control apparatus of a cabinet heat dissipation system is provided in an embodiment of the present disclosure. The apparatus includes: an obtaining unit, configured to obtain an operating parameter of the cabinet heat dissipation system; and a first control unit, configured to adjust a heat dissipation capacity of the cabinet heat dissipation system using a first adjustment manner, in case of determining, based on the operating parameter, that the cabinet heat dissipation system meets a first exception condition.

In a possible implementation, the first adjustment manner includes one or more of: adjusting a temperature and/or flow rate of a cooling medium at the liquid outlet at the secondary side of the CDU; and adjusting an opening degree of the first control valve.

In a possible implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In a possible implementation, the first control unit is configured to adjust a heat dissipation capacity of the cabinet heat dissipation system in one or more of: determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval; determining that the cabinet heat dissipation system meets the first exception condition and decreasing a cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, where the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1; determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval; determining that the cabinet heat dissipation system meets the first exception condition and adjusting an opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval; determining that the cabinet heat dissipation system meets the first exception condition and adjusting an opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval; determining that the cabinet heat dissipation system meets the first exception condition and increasing a cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate; determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and determining that the cabinet heat dissipation system meets the first exception condition and adjusting an opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

In a possible implementation, the apparatus further includes: a second control unit, configured to re-obtain the operating parameter of the cabinet heat dissipation system after the heat dissipation capacity of the cabinet heat dissipation system is adjusted at least once by the first control unit using the first adjustment manner; and adjust the heat dissipation capacity of the cabinet heat dissipation system using a second adjustment manner, in case of determining, based on the re-obtained operating parameter, that the cabinet heat dissipation system meets a second exception condition.

In a possible implementation, the second adjustment manner includes: switching a heat dissipation mode of the cabinet heat dissipation system.

In a possible implementation, the second control unit is configured to adjust a heat dissipation capacity of the cabinet heat dissipation system in one or more of: determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

In a possible implementation, an operating time interval of each heat dissipation mode of the cabinet heat dissipation system is longer than a preset time interval.

In a fourth aspect, an electronic device is provided in an embodiment of the present disclosure. The device includes a processor and a memory. The memory is configured to store a program executable by the processor. The processor is configured to read the program in the memory and perform the method as described in any of the embodiments in the second aspect.

In a fifth aspect, an embodiment of the present disclosure further provides a computer storage medium on which a computer program is stored. The computer program, when executed by a processor, implements the method as described in the second aspect.

In a sixth aspect, the present disclosure provides a computer program product. The computer program product includes a computer program code which, when executed on a computer, causes the computer to perform the method as described in any of the embodiments in the second aspect.

For technical effects that can be achieved in each of the third aspect, the fourth aspect, the fifth aspect, and the sixth aspect, reference may be made to the above description of the technical effects that can be achieved by various possible embodiments in the second aspect, which is not repeated here.

### BRIEF DESCRIPTION OF DRAWINGS

For clearer illustration of the technical solutions according to embodiments of the present disclosure, hereinafter briefly described are the drawings to be applied in embodiments of the present disclosure. Apparently, the drawings in the following descriptions are only some embodiments of the present disclosure, and other drawings may be obtained by those skilled in the art based on the provided drawings without any creative effort.

FIG. 1 is a schematic diagram of a connection relationship among a CDU, an air-liquid unit, and an air-liquid heat exchanger in a cabinet heat dissipation system according to an embodiment of the present disclosure;

FIG. 2 is a schematic diagram showing the principle of a first heat dissipation mode according to an embodiment of the present disclosure;

FIG. 3 is a schematic diagram showing the principle of a second heat dissipation mode according to an embodiment of the present disclosure;

FIG. 4 is a schematic diagram showing the principle of a third heat dissipation mode according to an embodiment of the present disclosure;

FIG. 5 is a schematic flow chart of a control method of a cabinet heat dissipation system according to an embodiment of the present disclosure;

FIG. 6 is a schematic diagram of a specific implementation process of a control method of a cabinet heat dissipation system according to an embodiment of the present disclosure;

FIG. 7 is a schematic structural diagram of a control apparatus of a cabinet heat dissipation system according to an embodiment of the present disclosure; and

FIG. 8 is a schematic structural diagram of an electronic device according to an embodiment of the present disclosure.

### DETAILED DESCRIPTION

In order to make the objectives, technical solutions and advantages of the present disclosure obvious, the disclosure is described in further detail below in conjunction with the accompanying drawings. Apparently, the described embodiments are only some, rather than all, of the embodiments of the present disclosure. Any other embodiments obtained by those of ordinary skills in the art based on the embodiments in the present disclosure without any creative effort shall fall within the protection scope of the present disclosure.

In the description of the embodiments of the present disclosure, unless otherwise stated, “/” means OR, for example, A/B refers to A or B. In addition, “and/or” is merely an association relationship describing associated objects and means that there may be three relationships. For example, A and/or B may indicate that A exists alone, both A and B exist, or B exists alone. In addition, in the description of the embodiment of the present disclosure, the plural form means two or more.

In the following description, terms “first”, “second”, and the like, are for descriptive purposes only and cannot be understood as indicating or implying relative importance or implicitly indicating quantities of indicated technical features. Therefore, a feature defined with “first” or “second” may explicitly or implicitly include one or more such feature.

Before introducing the cabinet heat dissipation system and the control method thereof provided by the embodiments of the present disclosure, for the sake of easy understanding, the technical background of the embodiments of the present disclosure is firstly introduced in detail.

With the development of data centers, the density of single cabinets is increased continuously. The traditional air-cooling mode can no longer meet the demands for heat dissipation, and the energy efficiency thereof cannot meet relevant requirements. In the future, data centers face various challenges in energy consumption and heat dissipation. A liquid cooling solution has become a development trend of future data centers. Cold plate liquid cooling is widely used as a relatively mature method for liquid cooling.

In practice, liquid cooling and air cooling are often used in combination with each other. When the two are used together, an air-liquid and liquid cooling systems are separated from each other, each requiring an independent liquid cooling system, which is difficult to manage in one stop, and the intelligence degree of control is low.

In view of this, a cabinet heat dissipation system and a control method and device thereof are provided in the embodiments of the present disclosure. The cabinet heat dissipation system includes a CDU, an air-liquid heat exchanger and a liquid dispensing unit. A primary side of the CDU is connected to a cold source, and a secondary side of the CDU is connected to the air-liquid heat exchanger and the liquid dispensing unit to provide a cooling medium for the air-liquid heat exchanger and the liquid dispensing unit. In other words, the cooling medium for the air-liquid heat exchanger and the liquid dispensing unit is provided by the CDU. By adjusting a temperature and/or flow rate of the cooling medium provided by the CDU, a heat dissipation capacity of the heat dissipation system can be adjusted, which contributes to one-stop management.

In the embodiment of the present disclosure, the first control valve is disposed in a pipeline of the liquid outlet at the secondary side of the CDU, and the second control valve is disposed on an outlet side of the air-liquid heat exchanger. By adjusting a flow direction of the cooling medium of the first control valve and the second control valve, a connection relationship between the liquid dispensing unit and the air-liquid heat exchanger can be changed, and thereby a heat dissipation mode of the cabinet heat dissipation system can be adjusted. By adjusting an opening degree of the first control valve and the second control valve, an air-to-liquid ratio can be adjusted. Thereby, intelligent control of the cabinet heat dissipation system can be realized, and a maximum energy saving can be achieved.

It should be noted that the cabinet mentioned in the embodiments of the present disclosure may be various types of cabinets in data center computer rooms. Various electronic devices capable of liquid cooling may be placed in the cabinet, such as a cold plate liquid-cooled server, a liquid-cooling pipeline of the cold plate liquid-cooled server being connected to the liquid dispensing unit.

After introducing the technical background of the embodiment of the present disclosure, the cabinet heat dissipation system and the control method thereof provided in the embodiments of the present disclosure are described in detail below in conjunction with specific embodiments.

Reference is made to FIG. 1, which is a schematic structural diagram of a cabinet heat dissipation system according to an embodiment of the present disclosure. The cabinet heat dissipation system includes: a controller, a CDU 10, and a liquid dispensing unit 11 and an air-liquid heat exchanger 12 for heat dissipation of the cabinet.

A primary side of the CDU 10 is connected to a cold source, and a liquid outlet at a secondary side of the CDU is connected to an inlet of the liquid dispensing unit 11 and an inlet of the air-liquid heat exchanger 12, respectively, through a first control valve 13.

The heat exchange on the primary side of the CDU may be a cooling medium or an air-liquid heat exchange unit. In other words, the primary side of the CDU may be air-cooled or liquid-cooled, which is not limited in the embodiment of the present disclosure.

In practice, the CDU 10 may be a rack-mounted CDU, which is installed at the bottom of the cabinet and does not occupy the space in the computer room. The primary side of the CDU 10 refers to a side where the CDU 10 performs heat exchange with an outdoor cold source; and the secondary side of the CDU 10 refers to a side where the CDU 10 performs heat exchange with the liquid dispensing unit 11 and the air-liquid heat exchanger 12 in the cabinet. In the embodiment of the present disclosure, the CDU 10 provides a cooling medium to the liquid dispensing unit 11 and the air-liquid heat exchanger 12. The cooling medium may be deionized water, ethylene glycol, propylene glycol, or the like, which is not limited in the embodiment of the present disclosure.

An outlet of the air-liquid heat exchanger 12 is connected to the inlet of the liquid dispensing unit 11 and a liquid return port at a secondary side of the CDU 10, respectively, through a second control valve 14.

In an implementation, the air-liquid heat exchanger 12 may be integrated into a rear door frame of the cabinet, that is, a rear door containing the air-liquid heat exchanger 12 is applied instead of a traditional rear door of the cabinet, so as to save the space of the computer room.

The air-liquid heat exchanger 12 may include merely a coiled radiator, which dissipates heat from the cabinet by using a fan of a device (such as a cold plate liquid-cooled server) in the cabinet, without providing a fan additionally, so as to be applicable for a scenario in which the power density is low and reduce energy consumption. Alternatively, the air-liquid heat exchanger 12 may include a coiled radiator and at least one fan, and dissipate heat from the cabinet by using a fan of a device in the cabinet, and assist and accelerate the heat dissipation by the at least fan. This is applicable for a scenario in which the power density is medium or large.

It should be noted that the first control valve and the second control valve in the embodiment of the present disclosure may be single devices, such as three-way solenoid valves, or independent control systems, such as control valves, balance valves, or flow meters having multiple branches, which perform opening/close, flow detection and control via a three-way pipeline. This is not limited in the embodiment of the present disclosure.

An outlet of the liquid dispensing unit 11 is connected to the liquid return port at the secondary side of the CDU. The liquid dispensing unit 11 is configured to provide the cooling medium provided by the CDU 10 to a device in the cabinet. In a case where multiple devices are arranged in the cabinet, the liquid dispensing unit 11 distributes the cooling medium provided by the CDU 10 to the multiple devices. There is no limit for the embodiment of the present disclosure on how to distribute specifically.

In a practical application, when the liquid dispensing unit 11 distributes the cooling medium provided by the CDU 10 to the devices, a flow control valve may be provided in a connection branch between the liquid dispensing unit 11 and each of the devices. In this way, the cooling medium distributed to each device is accurately controlled based on heat generation of each device, so that precise control of refrigeration is achieved.

The controller is configured to adjust a heat dissipation capacity of the cabinet heat dissipation system according to a preset control strategy.

In an implementation, the controller may obtain an operating parameter of the cabinet heat dissipation system, and adjust the heat dissipation capacity of the cabinet heat dissipation system based on the operating parameter of the cabinet heat dissipation system. The adjustment may be performed through one or more of: adjusting a temperature and/or flow rate of a cooling medium at the liquid outlet at the secondary side of the CDU; adjusting an opening degree of the first control valve and/or the second control valve; and switching a heat dissipation mode of the cabinet heat dissipation system.

The cabinet heat dissipation system provided by the embodiment of the present disclosure includes at least three heat dissipation modes, i.e., a first heat dissipation mode, a second heat dissipation mode and a third heat dissipation mode. An initial operation mode of the cabinet heat dissipation system may be any one of the three heat dissipation modes, which is not limited in the embodiment of the present disclosure.

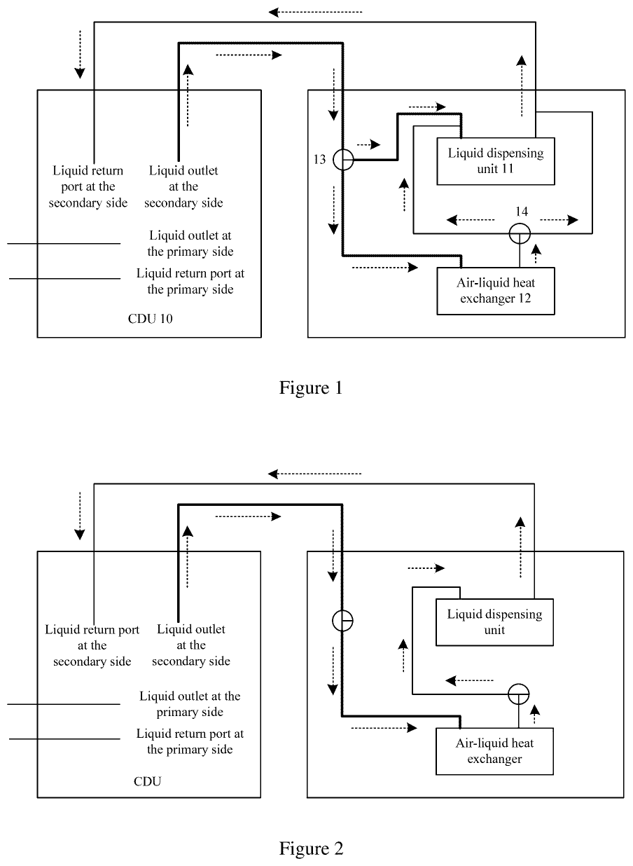

As shown in FIG. 2, in the first heat dissipation mode, the liquid outlet at the secondary side of the CDU is connected to the inlet of the air-liquid heat exchanger, the outlet of the air-liquid heat exchanger is connected to the inlet of the liquid dispensing unit, and the outlet of the liquid dispensing unit is connected to the liquid return port at the secondary side of the CDU.

In this heat dissipation mode, the cooling medium first passes through the air-liquid heat exchanger and then through the liquid dispensing unit. The cooling medium is recycled, which is applicable for a scenario with low power density.

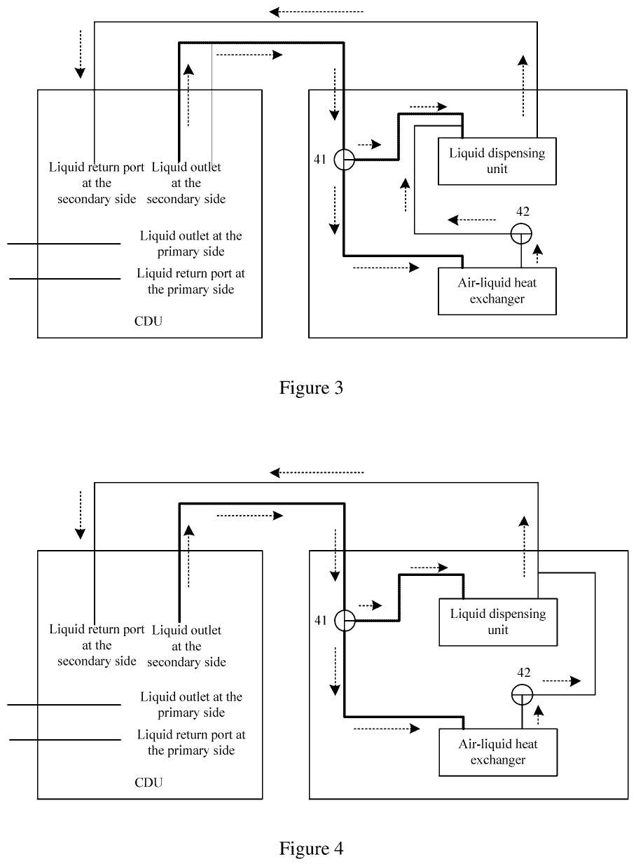

As shown in FIG. 3, in the second heat dissipation mode, the liquid outlet at the secondary side of the CDU is connected to the inlet of the air-liquid heat exchanger and the inlet of the liquid dispensing unit, the outlet of the air-liquid heat exchanger is connected to the inlet of the liquid dispensing unit, and the outlet of the liquid dispensing unit is connected to the liquid return port at the secondary side of the CDU.

In this heat dissipation mode, a part of the cooling medium is directly provided by the CDU to the liquid dispensing unit, and the other part of the cooling medium first passes through the air-liquid heat exchanger and is then provided to the liquid dispensing unit. The cooling medium is recycled. In this heat dissipation mode, a hot portion and a cold portion of the cooling media are mixed to cool the system and circulate heat, which is applicable for a scenario with medium power density.

As shown in FIG. 4, in the third heat dissipation mode, the liquid outlet at the secondary side of the CDU is connected to the inlet of the air-liquid heat exchanger and the inlet of the liquid dispensing unit, and the outlet of the air-liquid heat exchanger and the outlet of the liquid dispensing unit are both connected to the liquid return port at the secondary side of the CDU.

In this heat dissipation mode, the cooling medium provided by the CDU is divided into two portions, one branch is supplied to the air-liquid heat exchanger, and the other branch is supplied to the liquid dispensing unit. After heat exchange in the two branches, the cooling medium after heat exchange is merged and returned to the CDU, which is applicable for a scenario with high power density.

The cabinet heat dissipation system provided by the embodiment of the present disclosure is described above. In other embodiments of the present disclosure, the cabinet heat dissipation system may be connected to a control platform of the cabinet, the operating parameter of the cabinet heat dissipation system may be monitored through a display screen connected to the cabinet control platform, and adjustment of the heat dissipation capacity and switching of the heat dissipation mode may be controlled through the control platform.

In other embodiments of the present disclosure, a flow rate and temperature of each pipeline in the cabinet heat dissipation system may be further obtained. Based on differences of the obtained flow rate and temperature of each pipeline, a total cooling capacity and a real-time cooling capacity of the cabinet heat dissipation system and the cooling capacity of each of the air-liquid heat exchanger and the liquid dispensing unit in a parallel mode can be calculated.

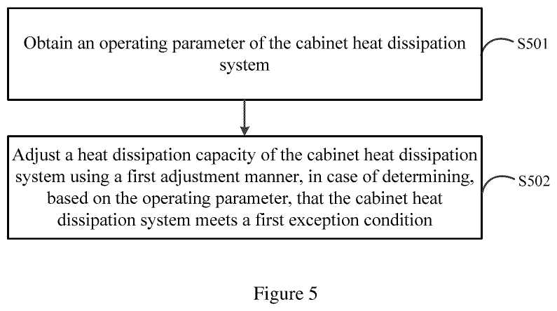

Reference is made to FIG. 5, which is a flow chart of a control method of a cabinet heat dissipation system according to an embodiment of the present disclosure. The method may be performed by a controller in the cabinet heat dissipation system. An implementation of the method includes steps S501 to S502.

In S501, an operating parameter of the cabinet heat dissipation system is obtained.

The operating parameter of the cabinet heat dissipation system may be measured and sampled by a sensor or a flow meter disposed at corresponding positions in the cabinet heat dissipation system.

In an implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In S502, a heat dissipation capacity of the cabinet heat dissipation system is adjusted using a first adjustment manner, in case of determining, based on the operating parameter, that the cabinet heat dissipation system meets a first exception condition.

The first adjustment manner includes one or more of: adjusting a temperature and/or flow rate of a cooling medium at the liquid outlet at the secondary side of the CDU; and adjusting an opening degree of the first control valve.

In an implementation, after the heat dissipation capacity of the cabinet heat dissipation system is adjusted at least once using the first adjustment manner, the operating parameter of the cabinet heat dissipation system is re-obtained; and the heat dissipation capacity of the cabinet heat dissipation system is adjusted using a second adjustment manner, in case of determining, based on the re-obtained operating parameter, that the cabinet heat dissipation system meets a second exception condition.

The second adjustment manner includes: switching a heat dissipation mode of the cabinet heat dissipation system.

In a practical application, in a case where it is determined that the cabinet heat dissipation system has abnormal heat dissipation based on the operating parameter of the cabinet heat dissipation system, the first adjustment manner is first applied to adjust the heat dissipation capacity of the cabinet heat dissipation system. For example, in a case that the heat dissipation mode remains unchanged, the heat dissipation capacity of the heat dissipation system is adjusted by adjusting a temperature and/or flow rate of the cooling medium at the liquid outlet at the secondary side of the CDU, and/or by adjusting the opening degree of the control valve. In a case where heat dissipation of the cabinet heat dissipation system is still abnormal after at least one adjustment using the first adjustment manner, the heat dissipation capacity of the cabinet heat dissipation system is then adjusted using the second manner, such as switching the heat dissipation mode. With the combination of the first adjustment manner and the second adjustment manner, the heat dissipation capacity of the cabinet heat dissipation system can be adjusted more accurately, so that the cabinet heat dissipation system can be adapted to more application scenarios and energy consumption can be saved.

In an implementation, the step of adjusting a heat dissipation capacity of the cabinet heat dissipation system using a first adjustment manner, in case of determining, based on the operating parameter, that the cabinet heat dissipation system meets a first exception condition, includes one or more of: determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval; determining that the cabinet heat dissipation system meets the first exception condition and decreasing a cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, where the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1; determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval; determining that the cabinet heat dissipation system meets the first exception condition and adjusting an opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval; determining that the cabinet heat dissipation system meets the first exception condition and adjusting an opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval; determining that the cabinet heat dissipation system meets the first exception condition and increasing a cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate; determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and determining that the cabinet heat dissipation system meets the first exception condition and adjusting an opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

In an implementation, the step of adjusting the heat dissipation capacity of the cabinet heat dissipation system using a second adjustment manner, in case of determining, based on the re-obtained operating parameter, that the cabinet heat dissipation system meets a second exception condition, includes one or more of: determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

A specific implementation of adjusting the heat dissipation capacity of the cabinet heat dissipation system using the first adjustment manner and the second adjustment manner is described in detail below with reference to a specific embodiment.

In order to facilitate explanation, the operating parameter of the cabinet heat dissipation system, an adjustment interval of the operating parameter, and a set value of the operating parameter are described below. Terms and meanings used in the description of the following embodiment are described, as can be seen in Table 1 below.

| Symbol | Meaning | Illustration |
|---|---|---|
| Ts0 | Temperature at the liquid | After adjustment of the temperature at the liquid |
| | outlet at the secondary side | outlet at the secondary side of the CDU, a |
| | of CDU | current temperature at the liquid outlet at the |
| | | secondary side of the CDU is still represented as |
| | | Ts0. |
| Ls0 | Flow rate at the liquid | After adjustment of the flow rate at the liquid |
| | outlet at the secondary side | outlet at the secondary side of the CDU, a |
| | of CDU | current flow rate at the liquid outlet at the |
| | | secondary side of the CDU is still represented as |
| | | Ls0. |
| [Ts1, Ts2] | Adjustment interval of | |
| | temperature at the liquid | |
| | outlet at the secondary side | |
| | of CDU | |
| [Ls1, Ls2] | Adjustment interval of | |
| | flow rate at the liquid | |
| | outlet at the secondary side | |
| | of CDU | |
| ΔT0 | Switching temperature set | |
| | point for the first heat | |
| | dissipation mode | |
| ΔT1 | Switching temperature set | |
| | point for the third heat | |
| | dissipation mode | |
| T0 | Temperature set point of | Correspond to the first preset temperature |
| | inlet of liquid dispensing | threshold in the embodiment of the present |
| | unit | disclosure |
| L0 | Flow rate set point of inlet | Correspond to the preset flow rate in the |
| | of liquid dispensing unit | embodiment of the present disclosure |
| [Tf1, Tf2] | Temperature interval | By adjusting the fan speed of the air-liquid heat |
| | adjustable by fan speed of | exchanger, the temperature on the rear door of |
| | air-liquid heat exchanger | the cabinet can be adjusted within this interval. |
| | | The fan is maintained at the highest speed when |
| | | the temperature on the rear door of the cabinet is |
| | | greater than the maximum of the interval; and |
| | | the fan is maintained at the lowest speed when |
| | | the temperature on the rear door of the cabinet is |
| | | less than the minimum in the interval. |
| | | Correspond to the first preset temperature |
| | | interval in the embodiment of the present |
| | | disclosure |
| C | Constant, redundancy | Correspond to the adjustment coefficient C in |
| | | the embodiment of the present disclosure |
| T1 | Temperature of cooling | |
| | medium at outlet of air- | |
| | liquid heat exchanger | |
| T2 | Temperature of cooling | |
| | medium at inlet of liquid | |
| | dispensing unit | |
| T3 | Temperature on rear door | |
| | of cabinet | |
| T4 | Temperature of cooling | |
| | medium at outlet of air- | |
| | liquid heat exchanger in | |
| | the third heat dissipation | |
| | mode | |
| T5 | Temperature at the liquid | |
| | return port at the secondary | |
| | side of CDU | |
| L1 | Flow rate at inlet of liquid | Flow rate at inlet of liquid dispensing unit in the |
| | dispensing unit | first heat dissipation mode and the second heat |
| | | dissipation mode |
| L2 | Flow rate at inlet of liquid | Flow rate at inlet of liquid dispensing unit in the |
| | dispensing unit | third heat dissipation mode |
| L3 | Flow rate at inlet of air- | Flow rate at inlet of air-liquid heat exchanger in |
| | liquid heat exchanger | the third heat dissipation mode |

It should be noted that an initial heat dissipation mode of the cabinet heat dissipation system may be any heat dissipation mode. In the following description, the initial heat dissipation mode is the first heat dissipation mode as an example. A specific implementation of adjusting the heat dissipation capacity of the cabinet heat dissipation system in the three heat dissipation modes is described in detail below.

1. The cabinet heat dissipation system operates in the first heat dissipation mode.

In a case where the cabinet heat dissipation system operates in the first heat dissipation mode, the liquid outlet at the secondary side of the CDU is connected to the inlet of the air-liquid heat exchanger, the outlet of the air-liquid heat exchanger is connected to the inlet of the liquid dispensing unit, and the outlet of the liquid dispensing unit is connected to the liquid return port at the secondary side of the CDU.

In a case where a temperature T1 of the cooling medium at the outlet of the air-liquid heat exchanger is less than T0, and a temperature T3 on the rear door of the cabinet is within the adjustment temperature interval [Tf1, Tf2] of the air-liquid heat exchanger, the first heat dissipation mode is maintained unchanged.

2. In the first heat dissipation mode, the heat dissipation capacity is adjusted using a first adjustment manner.

In a case where a temperature T1 of the cooling medium at the outlet of the air-liquid heat exchanger satisfies is greater than or equal to T0, or a temperature T3 on the rear door of the cabinet is greater than Tf2, the cabinet heat dissipation system first maintains the first heat dissipation mode unchanged and increases the cooling capacity provided by the CDU.

Specifically, to increase the cooling capacity provided by the CDU, the temperature Ts0 at the liquid outlet at the secondary side of the CDU may be decreased and/or a flow rate at the liquid outlet at the secondary side of the CDU may be increased. In practice, the temperature of the liquid outlet at the secondary side of the CDU and the flow rate of the liquid outlet at the secondary side of the CDU cannot be adjusted without limit, but follows the following restriction: Ts1≤Ts0≤Ts2; Ls1≤Ls0≤Ls2.

After the temperature Ts0 at the liquid outlet at the secondary side of the CDU is decreased and/or the flow rate Ls0 at the liquid outlet at the secondary side of the CDU is increased, it is determined again whether there is T1≤T0, L1≤L0, and T3 is within the interval [Tf1, Tf2]. In a case where there is T1≤T0, L1≤L0, and that T3 is within the interval [Tf1, Tf2], the cabinet heat dissipation system is re-balanced in the first heat dissipation mode.

It should be noted that, in practice, in a case where a temperature T3 on the rear door of the cabinet is less than Tf1, the cabinet heat dissipation system first maintains the first heat dissipation mode unchanged and decreases the cooling capacity provided by the CDU. For example, the temperature Ts0 at the liquid outlet at the secondary side of the CDU may be increased and/or the flow rate at the liquid outlet at the secondary side of the CDU may be decreased.

3. In the first heat dissipation mode, the heat dissipation capacity is adjusted using a second adjustment manner.

After the temperature Ts0 at the liquid outlet at the secondary side of the CDU is decreased and/or the flow rate Ls0 at the liquid outlet at the secondary side of the CDU is increased, it is determined again whether there is T1≤T0, L1≤L0, and T3 is within the interval [Tf1, Tf2]. In a case where one or more of the above three conditions are not satisfied after at least one adjustment, it is determined that the first heat dissipation mode cannot meet the current heat dissipation demand (cooling demand), and the cabinet heat dissipation system switches to the second heat dissipation mode.

4. The cabinet heat dissipation system operates in the second heat dissipation mode.

In a case where the cabinet heat dissipation system operates in the second heat dissipation mode, the liquid outlet at the secondary side of the CDU is connected to the inlet of the air-liquid heat exchanger and the inlet of the liquid dispensing unit respectively, the outlet of the air-liquid heat exchanger is connected to the inlet of the liquid dispensing unit, and the outlet of the liquid dispensing unit is connected to the liquid return port at the secondary side of the CDU.

In this heat dissipation mode, a part of the cooling medium provided by the secondary side of the CDU is mixed with the cooling medium after heat exchange by the air-liquid heat exchanger, and the mixture is supplied to the liquid dispensing unit. This heat dissipation mode requires that a temperature T2 of the mixed cooling medium at the inlet of the liquid dispensing unit satisfies T2≤T0, a flow rate L1 of the mixed cooling medium satisfies L1≤L0, and a temperature T3 on the rear door of the cabinet satisfies Tf1≤T3≤Tf2.

In a case where T2≤T0, L1≤L0, and Tf1≤T3≤Tf2 are all satisfied, it is determined that the cabinet heat dissipation system currently meets the heat dissipation demand. Due to the switching from the first heat dissipation mode to the second heat dissipation mode, the temperature at the liquid outlet at the secondary side of the CDU before switching is close to a lower limit, and the flow rate at the liquid outlet at the secondary side of the CDU before switching is close to an upper limit. Therefore, overcooling is possible.

Therefore, it may be determined whether T2, L1, and T3 satisfy the following condition: CT0≤T2≤T0, CL0≤L1≤L0, Tf1≤T3≤Tf2, where C is a constant representing a redundancy. When an actual temperature and flow rate of the cooling medium at the inlet of the liquid dispensing unit are close to T0 and L0 respectively, the power consumption is small, and the cabinet heat dissipation system continues operating in the second heat dissipation mode if T2, L1, and T3 all satisfy the above condition.

5. In the second heat dissipation mode, the heat dissipation capacity is adjusted using a first adjustment manner.

In a case where one or more operating parameters among T2, L1, or T3 do not satisfy the above condition, it is determined that the heat dissipation capacity is redundant, and the cooling capacity provided by the CDU is to be decreased.

Specifically, to decrease the cooling capacity provided by the CDU, the temperature Ts0 at the liquid outlet at the secondary side of the CDU may be increased and/or the flow rate at the liquid outlet at the secondary side of the CDU may be decreased, until an actual temperature and flow rate of the cooling medium at the inlet of the liquid dispensing unit are close to T0 and L0 respectively.

When adjusting the redundancy of T2 and L1, a condition T2≤T0 and L1≤L0 should be always satisfied. In a case where this condition is not satisfied, it is determined again whether T2 is too high, whether T3 is within the interval [Tf1, Tf2], and whether the flow rate L1 is less than or equal to L0.

In a case where temperature T2 is too high, it may be determined that the temperature of the cooling medium after heat exchange by the air-liquid heat exchanger is too high. It is necessary to adjust the opening degree of the first control valve to mix more cooling medium with the cooling medium after heat exchange by the air-liquid heat exchanger, to decrease the temperature of the cooling medium at the inlet of the liquid dispensing unit. Meanwhile, temperature T2 of the mixed cooling medium should satisfy T2≤T0, and the flow rate L1 of the mixed cooling medium should satisfy L1≤L0.

6. In the second heat dissipation mode, the heat dissipation capacity is adjusted using a second adjustment manner.

In a case where the temperature T2 is too high, if the condition T2≤T0 and L1≤L0 cannot be satisfied after adjusting the opening degree of the first control valve at least once to increase the flow rate of the cooling medium flowing to the liquid dispensing unit, it is determined that the cabinet heat dissipation system generates a large amount of heat and the second heat dissipation mode cannot meet the heat dissipation demand. Hence, the system is to be switched to the third heat dissipation mode.

After the heat dissipation mode is switched to the second heat dissipation mode, as the heat generation of the cabinet decreases and a difference between the temperature T5 at the liquid return port at the secondary side of the CDU and the temperature Ts0 at the liquid outlet at the secondary side of the CDU is less than ATO, it is determined that the cabinet heat dissipation system currently has a small heat exchange amount and can be switched to the first heat dissipation mode, which is more energy-saving. In a case where the difference between the temperature T5 at the secondary side return liquid port of the CDU and the temperature Ts0 at the secondary side outlet liquid port of the CDU is greater than or equal to ATO, indicating a large difference between the temperature of returned liquid of the CDU and the temperature of the supplied liquid, it is determined that the cabinet heat dissipation system has a large heat exchange amount and does not need to switch to the first heat dissipation mode.

7. The cabinet heat dissipation system operates in the third heat dissipation mode.

In a case where the cabinet heat dissipation system operates in the third heat dissipation mode, the liquid outlet at the secondary side of the CDU is connected to the inlet of the air-liquid heat exchanger and the inlet of the liquid dispensing unit respectively, and the outlet of the air-liquid heat exchanger and the outlet of the liquid dispensing unit are both connected to the liquid return port at the secondary side of the CDU.

In a case where T2≤T0 and L2≤L0 is satisfied, it is determined that the temperature and the flow rate of the cooling medium at the inlet of the liquid dispensing unit both meet the requirement. In this case, if the temperature T3 on the rear door of the cabinet satisfies Tf1≤T3≤Tf2, it is determined that the heat exchange of cold plates connected to the air-liquid heat exchanger and the liquid dispensing unit both meet the requirement, and heat dissipation of the cabinet is balanced in the third heat dissipation mode.

8. In the third heat dissipation mode, the heat dissipation capacity is adjusted using a first adjustment manner.

In a case of T2≤T0 and L2≤L0, if T3 does not satisfy Tf1≤T3≤Tf2, it is necessary to further determine whether T3 is greater than Tf2 or is less than Tf1.

In a case where T3 is greater than Tf2, it is determined that the temperature on the rear door of the cabinet is too high, the fan of the air-liquid heat exchanger is fully loaded but cannot reduce the temperature on the rear door of the cabinet. In this case, the opening degree of the first control valve is adjusted to adjust an air-to-liquid ratio and increase the flow rate L3 of the cooling medium of the air-liquid heat exchanger. After at least one adjustment, it is determined again whether T2≤T0, L2≤L0 and Tf1≤T3≤Tf2 is satisfied, and if satisfied, the balance in the third heat dissipation mode is reached again.

In a case where T3 is less than Tf1, it is determined that the heat exchange amount of the air-liquid heat exchanger is excessive. In this case, the opening degree of the first control valve is adjusted to decrease the flow rate of the cooling medium flowing to the air-liquid heat exchanger to reach balance in the third heat dissipation mode again.

When T2≤T0 and L2≤L0 is not satisfied, there are three situations, i.e., \textcircled{1} T2>T0, L2≤L0; \textcircled{2} T2>T0, L2>L0; and \textcircled{3} T2≤T0, L2>L0.

Situation \textcircled{1} indicates that for the cooling medium at the liquid outlet at the secondary side of the CDU, the flow rate meets the requirement but the temperature is too high. It is necessary to increase the cooling capacity provided by the CDU. Specifically, the temperature at the liquid outlet at the secondary side of the CDU may be decreased, and/or the flow rate at the liquid outlet at the secondary side of the CDU may be increased. Preferably, the temperature of the cooling medium at the liquid outlet at the secondary side of the CDU is decreased.

Situation \textcircled{2} indicates that for the cooling medium at the secondary side outlet of the CDU, the temperature is too high and the flow rate is too large. It is necessary to decrease both the temperature and the flow rate of the cooling medium at the secondary side outlet of the CDU.

Situation \textcircled{3} indicates that the temperature of the cooling medium at the secondary side outlet of the CDU is sufficient, but the flow rate of the cooling medium flowing to the liquid dispensing unit is too large. It is necessary to adjust the opening degree of the first control valve to increase the flow rate of the cooling medium flowing to the air-liquid heat exchanger and decrease the flow rate of the cooling medium flowing to the liquid dispensing unit.

9. In the third heat dissipation mode, the heat dissipation capacity is adjusted using a second adjustment manner.

When the cabinet heat dissipation system operates in the third heat dissipation mode, in case where the power density of the devices in the cabinet decreases, i.e. the generated heat in the cabinet decreases, in order to avoid refrigeration redundancy caused by long-term operation in the third heat dissipation mode, a comprehensive determination may be made based on: a difference between the temperature of the cooling medium at the outlet of the air-liquid heat exchanger and the temperature at the liquid outlet on the secondary side of the CDU (T4-Ts0), a difference between the temperature at the liquid return port at the secondary side of the CDU and the temperature at the liquid outlet at the secondary side of the CDU (T5-Ts0), and a relationship between the temperatures T3 on the rear door of the cabinet and Tf1.

When T4-Ts0≤ΔT0, T5-Ts0≤ΔT1, and T3<Tf1 are satisfied, it is determined that the temperature difference of the cooling medium passing through the air-liquid heat exchanger is small and the heat exchange amount is small, the temperature difference of the cooling medium passing through the liquid dispensing unit is small and the heat exchange amount is small, and the temperature on the rear door of the cabinet is lower than the minimum of the interval. The three conditions are all satisfied, indicating that the cooling capacity is redundant in the third heat dissipation mode. Hence, the system is switched to the second heat dissipation mode to reach a balance point again. On the contrary, when the above three conditions are not satisfied simultaneously, the third heat dissipation mode is to be maintain.

A specific implementation of adjusting the heat dissipation capacity in three heat dissipation modes of the cabinet heat dissipation system provided by the embodiment of the present disclosure is described in detail above. In the embodiment of the present disclosure, when the cabinet heat dissipation system operates in the third heat dissipation mode, ΔT0 and ΔT1 are utilized to determine whether to switch from the third heat dissipation mode to the second heat dissipation mode. In other embodiments of the present disclosure, it is possible to set ΔT2 for determining whether to switch from the third heat dissipation mode to the first heat dissipation mode. When the cabinet heat dissipation system operates in the second heat dissipation mode, ΔT3 may be set for determining whether to directly switch from the second heat dissipation mode to the third heat dissipation mode, to adapt to a scenario in which the heat of devices in the cabinet rises sharply and it is necessary to immediately switch to a mode having the maximum heat dissipation.

In addition, it should be noted that the adjustment of fan speed of the air-liquid heat exchanger in the embodiment of the present disclosure may be controlled based on a relationship between the temperature on the rear door of the cabinet and the temperature interval, or may be controlled based on a relationship between a pressure difference inside and outside the cabinet and a pressure difference interval.

In an implementation, it is assumed that the pressure difference inside and outside the cabinet is P, and the pressure difference interval is [Pf1, Pf2]. In a case where P is less than Pf1, the fan of the air-liquid heat exchanger operates at the lowest speed. In a case where P is greater than Pf2, the fan of the air-liquid heat exchanger operates at the highest speed. In a case where P is within the pressure difference interval [Pf1, Pf2], the fan speed is between the lowest speed and the highest speed, and is adjustable according to changes in the pressure difference.

In an implementation, in order to avoid influence on the operation of the heat dissipation system due to frequent switching of the heat dissipation mode, an operating time interval of the cabinet heat dissipation system in each heat dissipation mode is longer than a preset time interval. When the cabinet heat dissipation system operates in each heat dissipation mode, the operating parameter of the cabinet heat dissipation system may be collected for determining whether the heat dissipation capacity in the present heat dissipation mode needs to be adjusted. The preset time interval may be set based on actual experience, and this is not limited in the embodiment of the present disclosure.

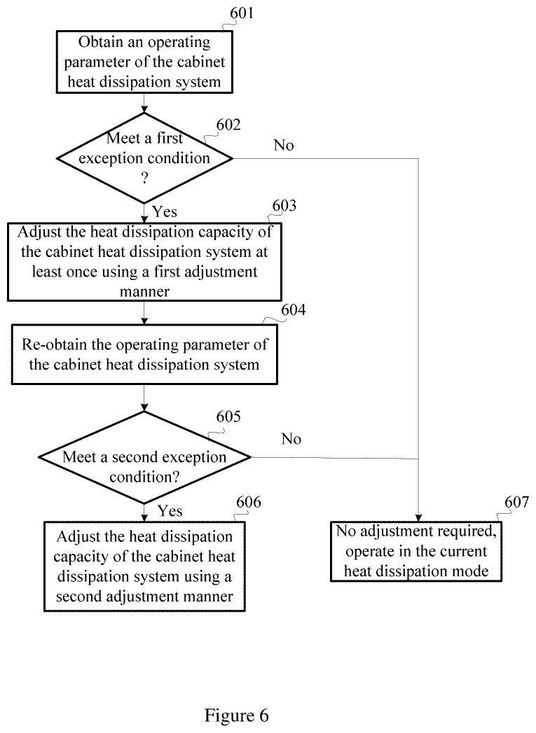

A specific implementation of the control method of a cabinet heat dissipation system provided in an embodiment of the present disclosure is described in detail below with reference to FIG. 6. As shown in FIG. 6, a specific implementation of the control method of a cabinet heat dissipation system provided in an embodiment of the present disclosure includes steps S601 to S607.

In S601, an operating parameter of the cabinet heat dissipation system is obtained.

In an implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In S602, it is determined, based on the operating parameter, whether the cabinet heat dissipation system meets a first exception condition. The method proceeds to S603 in a case where the first exception condition is met; and otherwise, the method proceeds to S607.

In S603, a heat dissipation capacity of the cabinet heat dissipation system is adjusted at least once using a first adjustment manner.

The first adjustment manner includes one or more of: adjusting a temperature and/or flow rate of a cooling medium at the liquid outlet at the secondary side of the CDU; and adjusting an opening degree of the first control valve.

In S604, an operating parameter of the cabinet heat dissipation system is re-obtained.

In S605, it is determined, based on the re-obtained operating parameter, whether the cabinet heat dissipation system meets a second exception condition. The method proceeds to S606 in a case where the second exception condition is met; and otherwise, the method proceeds to S607.

In S606, the heat dissipation capacity of the cabinet heat dissipation system is adjusted using a second adjustment manner.

The second adjustment manner includes: switching a heat dissipation mode of the cabinet heat dissipation system.

In S607, in a case where there is no abnormality in the cabinet heat dissipation system, no adjustment needs to be performed on the heat dissipation capacity and the present heat dissipation mode is maintained.

Based on the same concept, a control apparatus of a cabinet heat dissipation system is further provided in an embodiment of the present disclosure. The principle of problem solving of the apparatus is similar to the principle of problem solving of the method described above. The apparatus may be implemented with reference to the implementation of the method, and details are not repeated here.

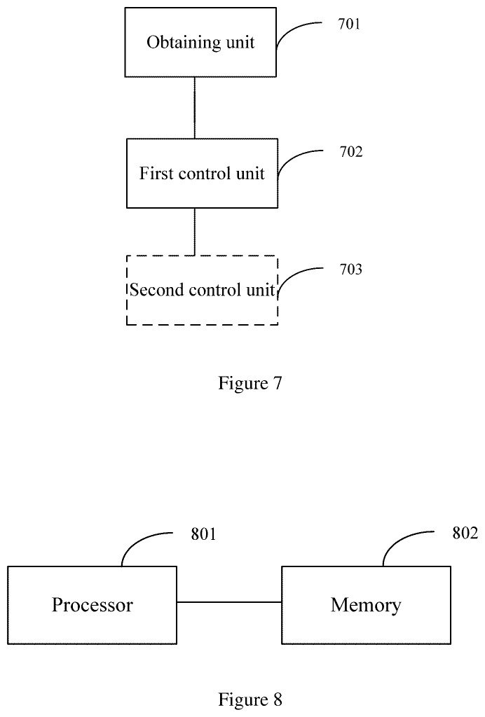

As shown in FIG. 7, a control apparatus of a cabinet heat dissipation system is provided in an embodiment of the present disclosure. The apparatus includes: an obtaining unit 701, configured to obtain an operating parameter of the cabinet heat dissipation system; and a first control unit 702, configured to adjust a heat dissipation capacity of the cabinet heat dissipation system using a first adjustment manner, in case of determining, based on the operating parameter, that the cabinet heat dissipation system meets a first exception condition.

In a possible implementation, the first adjustment manner includes one or more of: adjusting a temperature and/or flow rate of a cooling medium at the liquid outlet at the secondary side of the CDU; and adjusting an opening degree of the first control valve.

In a possible implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In a possible implementation, the first control unit 702 is configured to adjust a heat dissipation capacity of the cabinet heat dissipation system in one or more of: determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval; determining that the cabinet heat dissipation system meets the first exception condition and decreasing a cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, where the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1; determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval; determining that the cabinet heat dissipation system meets the first exception condition and adjusting an opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval; determining that the cabinet heat dissipation system meets the first exception condition and adjusting an opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval; determining that the cabinet heat dissipation system meets the first exception condition and increasing a cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate; determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and determining that the cabinet heat dissipation system meets the first exception condition and adjusting an opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

In a possible implementation, the apparatus further includes: a second control unit 703, configured to re-obtain the operating parameter of the cabinet heat dissipation system after the heat dissipation capacity of the cabinet heat dissipation system is adjusted at least once by the first control unit 702 using the first adjustment manner; and adjust the heat dissipation capacity of the cabinet heat dissipation system using a second adjustment manner, in case of determining, based on the re-obtained operating parameter, that the cabinet heat dissipation system meets a second exception condition.

In a possible implementation, the second adjustment manner includes: switching a heat dissipation mode of the cabinet heat dissipation system.

In a possible implementation, the second control unit 703 is configured to adjust the heat dissipation capacity of the cabinet heat dissipation system in one or more of: determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

In a possible implementation, an operating time interval of each heat dissipation mode of the cabinet heat dissipation system is longer than a preset time interval.

Based on the same concept, an electronic device is further provided in an embodiment of the present disclosure. The principle of problem solving of the device is similar to the principle of problem solving of the method described above. The device may be implemented with reference to the implementation of the method, and details are not repeated here.

As shown in FIG. 8, an electronic device is provided in an embodiment of the present disclosure. The electronic device includes a processor 801 and a memory 802 storing executable instructions for the processor 801. The processor 801 is configured to execute the executable instructions to implement the following steps: obtaining an operating parameter of the cabinet heat dissipation system; and adjusting a heat dissipation capacity of the cabinet heat dissipation system using a first adjustment manner, in case of determining, based on the operating parameter, that the cabinet heat dissipation system meets a first exception condition.

In a possible implementation, the first adjustment manner includes one or more of: adjusting a temperature and/or flow rate of a cooling medium at the liquid outlet at the secondary side of the CDU; and adjusting an opening degree of the first control valve.

In a possible implementation, the operating parameter of the cabinet heat dissipation system at least includes: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

In a possible implementation, the processor 801 is configured to adjust a heat dissipation capacity of the cabinet heat dissipation system in one or more of: determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval; determining that the cabinet heat dissipation system meets the first exception condition and decreasing a cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, where the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1; determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval; determining that the cabinet heat dissipation system meets the first exception condition and adjusting an opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval; determining that the cabinet heat dissipation system meets the first exception condition and adjusting an opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval; determining that the cabinet heat dissipation system meets the first exception condition and increasing a cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate; determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and determining that the cabinet heat dissipation system meets the first exception condition and adjusting an opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

In a possible implementation, the processor 801 is further configured to: re-obtain the operating parameter of the cabinet heat dissipation system after the heat dissipation capacity of the cabinet heat dissipation system is adjusted at least once using the first adjustment manner; and adjust the heat dissipation capacity of the cabinet heat dissipation system using a second adjustment manner, in case of determining, based on the re-obtained operating parameter, that the cabinet heat dissipation system meets a second exception condition.

In a possible implementation, the second adjustment manner includes: switching a heat dissipation mode of the cabinet heat dissipation system.

In a possible implementation, the processor 801 is configured to adjust the heat dissipation capacity of the cabinet heat dissipation system in one or more of: determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval; determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

In a possible implementation, an operating time interval of each heat dissipation mode of the cabinet heat dissipation system is longer than a preset time interval.

Based on the same inventive concept, a computer storage medium is provided in an embodiment of the present disclosure. The computer storage medium includes computer program code which, when executed on a computer, causes the computer to implement the control method of a cabinet heat dissipation system as described in any of the above embodiments. The computer storage medium follows a similar problem-solving principle to the control method of a cabinet heat dissipation system. Therefore, an implementation of the computer storage medium may be referred to the implementation of the method, and details are not repeated here.

In a specific implementation, the computer storage medium may include a universal serial bus (USB) flash drive, a mobile hard disk, a read-only memory (ROM), a random-access memory (RAM), a magnetic disk, an optical disk, and other storage media capable of storing program codes.

Based on the same inventive concept, a computer program product is further provided in an embodiment of the present disclosure. The computer program product includes computer program code which, when executed on a computer, causes the computer to implement the control method of a cabinet heat dissipation system as described in any of the above embodiments. The computer program product follows a similar problem-solving principle to the control method of a cabinet heat dissipation system. Therefore, an implementation of the computer program product may be referred to the implementation of the method, and details are not repeated here.

The computer program product may be implemented by any combination of one or more readable media. The readable medium may be a readable signal medium or a readable storage medium. The readable storage medium may be, but is not limited to, a system, an apparatus, or a device in an electronic, magnetic, optical, electromagnetic, infrared, or semi-conductive form, or any combination thereof. More specific examples (non-exhaustive list) of the readable storage medium include: an electrical connection with one or more wires, a portable disk, a hard disk, a random-access memory (RAM), a read-only memory (ROM), an erasable programmable read-only memory (EPROM or flash memory), an optical fiber, a portable compact disc read-only memory (CD-ROM), an optical storage device, a magnetic storage device or any suitable combination thereof.

Those skilled in the art should appreciate that embodiments of the present disclosure may be provided as a method, a system, or a computer program product. Thus, the present disclosure may be implemented by an entirely hardware embodiment, an entirely software embodiment, or an embodiment combining software and hardware. Furthermore, the present disclosure may be implemented as a computer program product embodied on one or more computer-usable storage media (including, but not limited to, a magnetic disk storage or an optical storage) embodying computer-usable program code therein.

The present disclosure is described with reference to flow charts and/or block diagrams of the method, the device (system), and the computer program product according to the embodiments of the present disclosure. It should be understood that each process and/or block in the flowchart illustrations and/or block diagrams, and combinations of processes and/or blocks in the flowchart illustrations and/or block diagrams, may be implemented by computer program instructions. The computer program instructions may be provided to a processor of a general-purpose computer, a dedicated computer, an embedded processor, or other programmable data processing device to produce a machine, such that the instructions executed by the processor of the computer or other programmable data processing device produce a device for implementing functions specified in one or more processes of the flowcharts and/or one or more blocks of the block diagrams.

The computer program instructions may be stored in a computer readable memory which is capable of guiding the computer or other programmable data processing device to operate in a certain manner, such that the instructions stored in the computer readable memory generate a product including an instruction apparatus which implements the functions specified in one or more processes of the flowcharts and/or one or more blocks of the block diagrams.

These computer program instructions may be loaded onto a computer or other programmable data processing device, causing a series of operating steps to be performed on the computer or other programmable device to produce computer-implemented processing, so that the instructions executed on the computer or other programmable device provide steps for implementing the functions specified in one or more processes of the flowcharts and/or one or more blocks of the block diagrams.

Various modifications and variations to the embodiments of the present disclosure can be made by those skilled in the art without departing from the spirit and scope of the present disclosure. Hence, as the modifications and variations of the present disclosure fall within the scope of the claims of the present disclosure and equivalents thereof, the present disclosure is also intended to include such modifications and variations.

What is claimed is:

1. A cabinet heat dissipation system, comprising: a controller, a cooling distribution unit CDU, and a liquid dispensing unit and an air-liquid heat exchanger for heat dissipation of the cabinet, wherein
a primary side of the CDU is connected to a cold source, and a liquid outlet at a secondary side of the CDU is connected to an inlet of the liquid dispensing unit and an inlet of the air-liquid heat exchanger, respectively, through a first control valve;
an outlet of the air-liquid heat exchanger is connected to the inlet of the liquid dispensing unit and a liquid return port at the secondary side of the CDU, respectively, through a second control valve;
an outlet of the liquid dispensing unit is connected to the liquid return port at the secondary side of the CDU; and
the controller is configured to adjust a heat dissipation capacity of the cabinet heat dissipation system according to a preset control strategy.

2. The cabinet heat dissipation system according to claim 1, wherein the controller is configured to adjust the heat dissipation capacity of the cabinet heat dissipation system in one or more of:
adjusting a temperature and/or flow rate of a cooling medium at the liquid outlet at the secondary side of the CDU;
adjusting an opening degree of the first control valve and/or the second control valve; and
switching a heat dissipation mode of the cabinet heat dissipation system.

3. The cabinet heat dissipation system according to claim 1, wherein heat dissipation modes of the cabinet heat dissipation system at least comprises a first heat dissipation mode, a second heat dissipation mode and a third heat dissipation mode;
in the first heat dissipation mode, the liquid outlet at the secondary side of the CDU is connected to the inlet of the air-liquid heat exchanger, the outlet of the air-liquid heat exchanger is connected to the inlet of the liquid dispensing unit, and the outlet of the liquid dispensing unit is connected to the liquid return port at the secondary side of the CDU;
in the second heat dissipation mode, the liquid outlet at the secondary side of the CDU is connected to the inlet of the air-liquid heat exchanger and the inlet of the liquid dispensing unit respectively, the outlet of the air-liquid heat exchanger is connected to the inlet of the liquid dispensing unit, and the outlet of the liquid dispensing unit is connected to the liquid return port at the secondary side of the CDU; and
in the third heat dissipation mode, the liquid outlet at the secondary side of the CDU is connected to the inlet of the air-liquid heat exchanger and the inlet of the liquid dispensing unit respectively, and the outlet of the air-liquid heat exchanger and the outlet of the liquid dispensing unit are both connected to the liquid return port at the secondary side of the CDU.

4. The cabinet heat dissipation system according to claim 3, wherein the controller is configured to adjust the heat dissipation capacity of the cabinet heat dissipation system using a first adjustment manner, in case of determining, based on an operating parameter of the cabinet heat dissipation system, that the cabinet heat dissipation system meets a first exception condition, through one or more of:
determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval;
determining that the cabinet heat dissipation system meets the first exception condition and decreasing the cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, wherein the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1;
determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than the first preset temperature threshold, a flow rate at the inlet of the liquid dispensing unit is less than or equal to the preset flow rate, and a temperature on the rear door of the cabinet is within the first preset temperature interval;
determining that the cabinet heat dissipation system meets the first exception condition and adjusting the opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval;
determining that the cabinet heat dissipation system meets the first exception condition and adjusting the opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval;
determining that the cabinet heat dissipation system meets the first exception condition and increasing the cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate;
determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and
determining that the cabinet heat dissipation system meets the first exception condition and adjusting the opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

5. The cabinet heat dissipation system according to claim 4, wherein the controller is configured to:
re-obtain the operating parameter of the cabinet heat dissipation system, after adjusting the heat dissipation capacity of the cabinet heat dissipation system at least once using the first adjustment manner; and
adjust the heat dissipation capacity of the cabinet heat dissipation system using a second adjustment manner, in case of determining, based on the re-obtained operating parameter, that the cabinet heat dissipation system meets a second exception condition.

6. The cabinet heat dissipation system according to claim 5, wherein the second adjustment manner comprises: switching a heat dissipation mode of the cabinet heat dissipation system.

7. The cabinet heat dissipation system according to claim 6, wherein the controller is configured to adjust the heat dissipation capacity of the cabinet heat dissipation system using the second adjustment manner, in case of determining, based on the re-obtained operating parameter, that the cabinet heat dissipation system meets the second exception condition, through one or more of:
determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval;
determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval;
determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and
determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

8. The cabinet heat dissipation system according to claim 7, wherein the operating parameter of the cabinet heat dissipation system at least comprises: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

9. The cabinet heat dissipation system according to claim 3, wherein an operating time interval of each heat dissipation mode of the cabinet heat dissipation system is longer than a preset time interval.

10. The cabinet heat dissipation system according to claim 1, wherein the air-liquid heat exchanger comprises a coiled radiator.

11. The cabinet heat dissipation system according to claim 10, wherein the air-liquid heat exchanger further comprises at least one fan.

12. A method for controlling the cabinet heat dissipation system according to claim 1, the method comprising:
obtaining an operating parameter of the cabinet heat dissipation system;
adjusting a heat dissipation capacity of the cabinet heat dissipation system using a first adjustment manner, in case of determining, based on the operating parameter, that the cabinet heat dissipation system meets a first exception condition.

13. The method according to claim 12, wherein the first adjustment manner comprises one or more of:
adjusting a temperature and/or flow rate of a cooling medium at the liquid outlet at the secondary side of the CDU; and
adjusting an opening degree of the first control valve.

14. The method according to claim 12, wherein the operating parameter of the cabinet heat dissipation system at least comprises: a temperature of a cooling medium at the outlet of the air-liquid heat exchanger, a temperature of a cooling medium at the inlet of the liquid dispensing unit, a temperature on a rear door of the cabinet, a temperature at the liquid return port at the secondary side of the CDU, a temperature at the liquid outlet at the secondary side of the CDU, a flow rate at the inlet of the liquid dispensing unit, and a flow rate at the inlet of the air-liquid heat exchanger.

15. The method according to claim 14, wherein the adjusting of the heat dissipation capacity of the cabinet heat dissipation system using the first adjustment manner, in case of determining, based on the operating parameter, that the cabinet heat dissipation system meets the first exception condition, comprises one or more of:
determining that the cabinet heat dissipation system meets the first exception condition and increasing a cooling capacity provided by the CDU, in a case where the cabinet heat dissipation system is in the first heat dissipation mode, a temperature of the cooling medium at the outlet of the air-liquid heat exchanger is greater than or equal to a first preset temperature threshold, or a temperature on the rear door of the cabinet is greater than a maximum of a first preset temperature interval;
determining that the cabinet heat dissipation system meets the first exception condition and decreasing the cooling capacity provided by the CDU, in a case where the cabinet heat dissipation system is in the second heat dissipation mode, a temperature of the cooling medium at the inlet of the liquid dispensing unit is less than a target temperature, or a flow rate at the inlet of the liquid dispensing unit is less than a target flow rate, or a temperature on the rear door of the cabinet is less than a minimum of the first preset temperature interval, wherein the target temperature is equal to a product of the first preset temperature threshold and an adjustment coefficient C, the target flow rate is equal to a product of a preset flow rate and the adjustment coefficient C, and the adjustment coefficient C is greater than or equal to 0 and less than or equal to 1;
determining that the cabinet heat dissipation system meets the first exception condition and adjusting an opening degree of the first control valve to increase a flow rate of the cooling medium flowing to the liquid dispensing unit, in a case where the cabinet heat dissipation system is in the second heat dissipation mode, a temperature of the cooling medium at the inlet of the liquid dispensing unit is greater than or equal to the first preset temperature threshold, a flow rate at the inlet of the liquid dispensing unit is less than or equal to the preset flow rate, and a temperature on the rear door of the cabinet is within the first preset temperature interval;
determining that the cabinet heat dissipation system meets the first exception condition and adjusting the opening degree of the first control valve to increase a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is greater than a maximum of the first preset temperature interval;
determining that the cabinet heat dissipation system meets the first exception condition and adjusting the opening degree of the first control valve to decrease a flow rate of the cooling medium flowing to the air-liquid heat exchanger, in a case where the cabinet heat dissipation system is in the third heat dissipation mode, a temperature of the cooling medium at the inlet of the liquid dispensing unit is less than or equal to the first preset temperature threshold, a flow rate at the inlet of the liquid dispensing unit is less than or equal to the preset flow rate, and a temperature on the rear door of the cabinet is less than a minimum of the first preset temperature interval;
determining that the cabinet heat dissipation system meets the first exception condition and increasing the cooling capacity provided by the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is less than or equal to the preset flow rate;
determining that the cabinet heat dissipation system meets the first exception condition and decreasing a temperature and a flow rate at the liquid outlet at the secondary side of the CDU, in a case where the cabinet heat dissipation system is in the third heat dissipation mode, a temperature of the cooling medium at the inlet of the liquid dispensing unit is greater than the first preset temperature threshold, and a flow rate at the inlet of the liquid dispensing unit is greater than the preset flow rate; and
determining that the cabinet heat dissipation system meets the first exception condition and adjusting the opening degree of the first control valve to increase a flow rate of the cooling medium flowing to the air-liquid heat exchanger and decrease a flow rate of the cooling medium flowing to the liquid dispensing unit, in a case where the cabinet heat dissipation system is in the third heat dissipation mode, a temperature of the cooling medium at the inlet of the liquid dispensing unit is less than or equal to the first preset temperature threshold, and a flow rate at the inlet of the liquid dispensing unit is greater than the preset flow rate.

16. The method according to claim 12, further comprising:
re-obtaining the operating parameter of the cabinet heat dissipation system, after adjusting the heat dissipation capacity of the cabinet heat dissipation system at least once using the first adjustment manner; and
adjusting the heat dissipation capacity of the cabinet heat dissipation system using a second adjustment manner, in case of determining, based on the re-obtained operating parameter, that the cabinet heat dissipation system meets a second exception condition.

17. The method according to claim 16, wherein the second adjustment manner comprises: switching a heat dissipation mode of the cabinet heat dissipation system.

18. The method according to claim 17, wherein the adjusting of the heat dissipation capacity of the cabinet heat dissipation system using the second adjustment manner, in case of determining, based on the re-obtained operating parameter, that the cabinet heat dissipation system meets the second exception condition, comprises one or more of:
determining that the cabinet heat dissipation system meets the second exception condition and switching the heat dissipation mode of the cabinet heat dissipation system to the second heat dissipation mode, in a case where the cabinet heat dissipation system is in the first heat dissipation mode, a temperature of the cooling medium at the outlet of the air-liquid heat exchanger is greater than or equal to the first preset temperature threshold, or a flow rate at the inlet of the liquid dispensing unit is greater than the preset flow rate, or a temperature on the rear door of the cabinet is greater than a maximum of the first preset temperature interval;
determining that the cabinet heat dissipation system meets the second exception condition and switching the heat dissipation mode of the cabinet heat dissipation system to the third heat dissipation mode, in a case where the cabinet heat dissipation system is in the second heat dissipation mode, a temperature of the cooling medium at the inlet of the liquid dispensing unit is greater than the first preset temperature threshold, or a flow rate at the inlet of the liquid dispensing unit is greater than the preset flow rate, or a temperature on the rear door of the cabinet is greater than a maximum of the first preset temperature interval;
determining that the cabinet heat dissipation system meets the second exception condition and switching the heat dissipation mode of the cabinet heat dissipation system to the first heat dissipation mode, in a case where the cabinet heat dissipation system is in the second heat dissipation mode, and a difference between a temperature at the liquid return port at the secondary side of the CDU and a temperature of the liquid outlet at the secondary side of the CDU is less than a second preset temperature threshold; and
determining that the cabinet heat dissipation system meets the second exception condition and switching the heat dissipation mode of the cabinet heat dissipation system to the second heat dissipation mode, in a case where the cabinet heat dissipation system is in the third heat dissipation mode, a difference between a temperature of the cooling medium at the outlet of the air-liquid heat exchanger and a temperature at the liquid outlet at the secondary side of the CDU is less than or equal to the second preset temperature threshold, and a difference between a temperature at the liquid return port at the secondary side of the CDU and a temperature at the liquid outlet at the secondary side of the CDU is less than or equal to a third preset temperature threshold, and a temperature on the rear door of the cabinet is less than a minimum of the first preset temperature interval.

19. The method according to claim 12, wherein an operating time interval of each heat dissipation mode of the cabinet heat dissipation system is longer than a preset time interval.

20. An electronic device, comprising: a processor; and a memory storing executable instructions by a processor, the processor, when executing the executable instructions, performing steps of the method according to claim 12.
